(19) United States
(12) Patent Application Publication
(10) Pub. No.: US 2024/0234200 A1
(43) Pub. Date: Jul. 11, 2024

(54) APPARATUSES FOR THERMAL MANAGEMENT OF A PEDESTAL AND CHAMBER

(71) Applicant: Lam Research Corporation, Fremont, CA (US)

(72) Inventors: Aaron Blake Miller, West Linn, OR (US); Aaron Durbin, Portland, OR (US); Ramesh Chandrasekharan, Portland, OR (US); Bradley Taylor Streng, Tigard, OR (US)

(21) Appl. No.: 18/563,666

(22) PCT Filed: May 26, 2022
(86) PCT No.: PCT/US22/72603

§ 371 Date: Nov. 22, 2023

Related U.S. Application Data
(60) Provisional application No. 63/202,154, filed on May 28, 2021.

(51) Int. Cl. H01L 21/687; H01L 21/67

(52) U.S. Cl. CPC H01L 21/68785; H01L 21/67115; H01L 21/68735

(57) ABSTRACT

Apparatuses not only capable of reducing unwanted radiative heat loss from a pedestal of a substrate processing system, but also capable of reducing radiative heat transfer to other components within a chamber of the substrate processing system.

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Many semiconductor processes are performed on a wafer that is maintained at temperatures above ambient or room temperature. A substrate support structure, e.g., a pedestal, with one or more heating elements is generally used to heat the wafer to the desired temperatures.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

Some aspects provide a thermal shield not only capable of reducing unwanted radiative heat loss from a pedestal of a substrate processing system, but also capable of reducing radiative heat transfer to other components within a chamber of the substrate processing system.

Some aspects provide a thermal shield collar not only capable of reducing unwanted radiative heat loss from a pedestal of a substrate processing system, but also capable of reducing radiative heat transfer to other components within a chamber of the substrate processing system.

Some aspects provide an apparatus including the thermal shield and the thermal shield collar that are not only capable of reducing unwanted radiative heat loss from a pedestal of a substrate processing system, but also capable of reducing radiative heat transfer to other components within a chamber of the substrate processing system.

Additional aspects will be set forth in the detailed description which follows, and, in part, will be apparent from the disclosure, or may be learned by practice of the inventive concepts.

According to some embodiments, a thermal shield for use in a semiconductor processing chamber includes a body. The body has a substantially annular shape that extends around a center axis and that is at least partially defined by an outermost circumferential boundary that ranges between about 12 inches and about 16 inches and an innermost boundary. The body is formed of a ceramic material. The body has a thickness that is less than or equal to 0.5 inches.

In some embodiments, the body may further include a first annular region that extends around the center axis. The first annular region may have an outer circumferential boundary, an inner boundary, a radial width spanning between the outer circumferential boundary and the inner boundary in a direction perpendicular to the center axis, and a first thickness in a direction parallel to the center axis that decreases as a function of proximity to the center axis. The first thickness may be less than or equal to 0.5 inches.

In some embodiments, at the outer circumferential boundary of the first annular region, the body may have an outer first thickness in the direction parallel to the center axis that is between about 0.01 inches and 0.5 inches. At the inner boundary of the first annular region, the body may have an inner first thickness in the direction parallel to the center axis. The inner first thickness may be less than the outer first thickness and is between about 0.01 inches and 0.5 inches.

In some embodiments, the radial width of the annular region may range between about 0.01 inches and 0.5 inches.

In some embodiments, the body may further include a second annular region that extends around the center axis. The second annular region may have a second radial width in a direction perpendicular to the center axis, and a second thickness in a direction parallel to the center axis that remains substantially constant along the second radial width.

In some embodiments, the body may include a plurality of holes configured for lift pins to pass through.

According to some embodiments, a thermal shield collar for use in a semiconductor processing chamber includes a collar body. The collar body has a tubular shape with a collar inner circumferential boundary and a collar outer circumferential boundary that both extend around a collar center axis and further has a length that extends along the collar center axis. The collar body is formed of a ceramic material. The collar body includes a top region and a bottom region, a bottom surface in the bottom region, and a plurality of feet in the bottom region, each foot having a support surface and each foot extending away from the bottom surface along the collar center axis by at least a first distance such that each support surface is offset from the bottom surface by at least the first distance.

In some embodiments, the collar body may further include a first tubular region that may extend around the collar center axis, may be at least partially defined by a first collar top circumferential boundary and a first collar bottom circumferential boundary offset from the first collar top circumferential boundary by a first height along the collar center axis of the collar body, and may have a tapered thickness in a direction perpendicular to the collar center axis and along the collar center axis that decreases as the distance from the top region increases. The first collar top circumferential boundary may be closer to the top region than the first collar bottom circumferential boundary.

In some embodiments, at the first collar top circumferential boundary, the collar body may have a first collar thickness in the direction perpendicular to the collar center axis. At the first collar bottom circumferential boundary, the collar body may have a second collar thickness in the direction perpendicular to the collar center axis that is less than the first collar thickness.

In some embodiments, the collar body may include a second tubular region positioned in at least the top region and at least partially defined by a second collar top circumferential boundary and a second collar bottom circumferential boundary offset from the second collar top circumferential boundary by a second height along the collar center axis. The second tubular region may have a third thickness in a direction perpendicular to the collar center axis that remains substantially constant along the collar center axis.

In some embodiments, the collar body may include one or more second mating surfaces in the top region that are configured to interface with one or more first mating surfaces of a thermal shield. Each second mating surface may be separate from the other mating surfaces and may have the shape of a segment defined by an arc and a line joining the end points thereof.

In some embodiments, the collar body may further include a plurality of constraint surfaces in the top region. Each constraint surface may face away from the collar center axis, may intersect with a corresponding one of the second mating surfaces such that each constraint surface is at least partially defined by the line of the corresponding second mating surface, and may be oriented at a non-parallel angle to the corresponding second mating surface.

According to some embodiments, an apparatus includes a semiconductor processing chamber, a substrate support, a thermal shield, and a thermal shield collar. The substrate support is configured to support a wafer and has a pedestal base and a support column under the pedestal base. The thermal shield includes a body having a substantially annular shape that extends around a center axis and that is at least partially defined by an outermost circumferential boundary that ranges between about 12 inches and about 16 inches and an innermost boundary. The body is formed of a ceramic material, includes one or more first mating surfaces within an annular region adjacent to the innermost boundary, and has a thickness that is less than or equal to 0.5 inches. The thermal shield collar has a collar body formed of the ceramic material. The collar body has a tubular shape with a collar inner circumferential boundary and a collar outer circumferential boundary that both extend around a collar center axis and a length that extends along the collar center axis, a top region and a bottom region, one or more support surfaces in the bottom region, and one or more second mating surfaces in the top region that are configured to interface with the one or more first mating surfaces of the thermal shield. The thermal shield is positioned underneath the pedestal base and offset from a bottom surface of the pedestal base by a first distance that ranges between about 0.1 inches and about 2 inches. The thermal shield is positioned on and supported by the thermal shield collar. The center axis and the collar center axis are collinear. At least a portion of the support column is positioned inside and extends through the thermal shield collar. The one or more support surfaces are supported by the substrate support. The one or more first mating surfaces are in contact with the one or more second mating surfaces.

In some embodiments, the apparatus may further include a chamber shield. The chamber shield may include a bottom and one or more side walls extending from the bottom. The semiconductor processing chamber may include one or more chamber walls and a chamber bottom. The chamber shield may be positioned in the semiconductor processing chamber such that the bottom of the chamber shield is adjacent to and offset from the chamber bottom by a first offset distance, the chamber shield is supported by one or more supports that span between the chamber shield bottom and the chamber bottom, the one or more side walls of the chamber shield are adjacent to and offset from the one or more chamber walls by a second offset distance, and the pedestal base, the thermal shield, and the thermal shield collar are positioned above the bottom of the chamber shield.

In some embodiments, the first offset distance may be between about 0.05 inches and about 2 inches, and the second offset distance may be between about 0.05 inches and about 2 inches.

In some embodiments, the apparatus may further include a showerhead positioned in the chamber. The showerhead may have an outer surface that faces the substrate support, and the one or more side walls of the chamber shield may be vertically offset above the outer surface of the showerhead when viewed at an angle perpendicular to the center axis.

In some embodiments, the collar body may further include one or more constraint surfaces in the top region. When the one or more first mating surfaces are in contact with the one or more second mating surfaces, the one or more constraint surfaces may prevent radial movement of the thermal shield with respect to the collar center axis.

In some embodiments, the body of the thermal shield may include an annular region that extends around the center axis. The annular region may have an outer circumferential boundary, an inner boundary, a radial width spanning between the outer circumferential boundary and the inner boundary in a direction perpendicular to the center axis, and a first thickness in a direction parallel to the center axis that decreases as the radial distance decreases as a function of proximity to the center axis. The first thickness may be less than or equal to 0.5 inches.

In some embodiments, the collar body of the thermal shield collar may include a first tubular region, which may extend around the collar center axis and may be at least partially defined by a first collar top circumferential boundary and a first collar bottom circumferential boundary offset from the first collar top circumferential boundary by a first height along the collar center axis of the collar body. The first collar top circumferential boundary may be closer to the top region than the first collar bottom circumferential boundary. The first tubular region may have a second thickness in a direction perpendicular to the collar center axis and along the collar center axis that decreases as the distance from the top region increases.

In some embodiments, the thermal shield collar may include a plurality of feet in the bottom region and a bottom surface in the bottom region. Each foot may include one of the support surfaces. Each foot may extend away from the bottom surface along the collar center axis by a second distance such that the corresponding support surface is offset from the bottom surface by the second distance. The support surfaces may be in contact with a collar support surface of the substrate support. The bottom surfaces may not be in contact with the collar support surface.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1A depicts an off-angle view of a thermal shield positioned on a thermal shield collar.

FIG. 1B depicts an exploded view of FIG. 1A.

FIG. 2 depicts an example processing chamber schematic.

FIG. 3 depicts a top view of the thermal shield of FIG. 1A.

FIG. 4 depicts a representative cross-sectional side view slice of one half of the thermal shield of FIG. 3.

FIG. 5A depicts a top view of the thermal shield collar of FIGS. 1A and 1B.

FIG. 5B depicts a magnified view of one mating surface in FIG. 5A.

FIG. 5C depicts a top view of the collar of FIG. 5A and a portion of a thermal shield positioned thereon.

FIG. 6 depicts a representational, magnified cross-sectional side view slice of the thermal shield of FIG. 4 and a part of a thermal shield collar.

FIG. 7A depicts a side view of the collar of FIGS. 1A and 1B.

FIG. 7B depicts a representative cross-sectional side view slice of a portion of the thermal shield collar of FIG. 7A.

FIG. 8 depicts a cross-sectional side view of a representational schematic of a pedestal base, a thermal shield, and a thermal collar.

### DETAILED DESCRIPTION

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In this application, the terms “semiconductor wafer,” “wafer,” “substrate,” “wafer substrate” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of the disclosed embodiments include various articles such as printed circuit boards, magnetic recording media, magnetic recording sensors, mirrors, optical elements, micro-mechanical devices and the like.

### Introduction and Context

Many semiconductor processes heat and maintain a wafer at temperatures above ambient or room temperature, such as above at least 20° C., including temperatures between about 50° C. and 500° C., for example. The wafer may be heated by one or more heating elements within a substrate support structure, such as a pedestal or electrostatic chuck (“ESC”); as used herein, the term “pedestal” is used to collectively refer to any substrate support structure, including an ESC. The heating elements within the pedestal, such as resistive heating elements, generate heat that is conducted and/or radiated to the wafer, but also radiated as heat loss to other parts of the processing chamber. Many semiconductor processing chambers are able to withstand radiation heat loss from the pedestal within typical temperature operating ranges, such as between about 50° C. and 500° C., for example.

However, new and novel processing techniques are using temperatures above 500° C., including above 550° C., above 600° C., above 650° C., above 700° C., and above 750° C., for instance. The present inventors discovered that operating at these higher temperatures poses unique challenges to managing the thermal environment in the processing chamber, including preventing unwanted heat loss and damage to components within the processing chamber. For example, the radiation heat loss of some pedestals at these higher temperatures is greater than at lower temperatures, such as about 35% higher at 650° C. as compared to at 550° C. Radiation heat loss can result in multiple adverse effects. The higher the radiation heat loss, the higher the energy consumption by the pedestal (and the more power is required) in order to maintain the desired target temperature. This can cause additional thermal stress on the pedestal's internal components due to the higher power throughput and cause them to be more likely to fail. Surrounding components within the chamber, such as the showerhead and chamber walls, can also absorb the radiation heat loss and the higher the radiation heat loss, the higher the energy absorbed by these other components which can cause them to overheat and become damaged. The present inventors thus conceived of specially designed heat shields that reduced the radiation heat loss from pedestals operating at temperatures above 550° C., above 600° C., above 650° C., above 700° C., and above 750° C., for example.

The present inventors determined that the use of novel thermal shields underneath a pedestal can reduce unwanted radiation heat loss from the pedestal. The thermal shields serve as thermal insulators under the pedestal to mitigate heat loss via thermal radiation, thereby reducing the amount of power needed to maintain the pedestal at a particular elevated temperature and also preventing other components within the chamber from overheating due to excess heat radiated from the pedestal.

### Thermal Shields

Aspects of this disclosure pertain to thermal shields under the pedestal that reduce unwanted radiative heat loss from the pedestal and reduce radiative heat transfer to other components within the processing chamber. One thermal shield has a thin annular-shaped body with a high view factor relative to the underside of the pedestal in order to receive a high amount of thermal radiation from the pedestal. The annular-shaped thermal shield, referred to herein as the “annular shield” or “thermal shield”, also has various features to reduce thermal conduction and radiation to other components, such as a low thermal mass, a composition of a thermally insulative material, such as a ceramic, geometric features for increasing thermal resistance, low emissivity, and geometric features for increasing the contact resistance between the annular thermal shield and the structure supporting the shield, a thermal shield collar.

The thermal shield collar, also referred to herein as the “collar” or “thermal collar”, extends around, but is radially offset from, the pedestal's support column. The annular shield may only be in contact with the collar and it is therefore desirable to reduce heat transfer from the thermal shield to the collar. Heat transfer between these elements can be reduced by increasing the contact resistance where they contact each other, which can be accomplished by reducing their contact surface area and/or by decreasing their thermal mass at the contact area(s). The higher the contact resistance, the lower the heat loss and transfer from the thermal shield to the collar. Heat transfer between these elements can also be reduced by increasing the thermal resistance of these elements, such as by reducing the component's cross-sectional area. In some implementations, an annular region of the thermal shield may have a tapered thickness that decreases as the radial distance from the annular shield's center decreases, thereby creating a knife edge shape where it contacts the collar.

It is also desirable to reduce the heat transfer from the thermal shield collar to the structure that supports it. Similar to above, thermal transfer along the length of the collar from where it is in contact with the thermal shield to where it is in contact with the support structure may be reduced by increasing the collar's thermal resistance with a decreased cross-sectional area, as well as reduced contact surfaces with the support structure. Additionally, similar to the thermal shield, the collar may have a tapered thickness within a tubular region along the length of the collar that decreases in thickness as the distance from annular shield increases. In some implementations, the collar may have limited contact with the support structure by having one or more feet that each contact the support structure to reduce the contact surface area and thereby reduce the thermal contact between the collar and the support structure. In some embodiments, the thermal shield and the collar may be used independently or together as aspects of a heat shield system in a semiconductor processing chamber.

In some embodiments, a chamber shield may be additionally, or alternatively, used to reduce the pedestal's radiation heat loss from reaching the chamber walls and bottom. The chamber shield may have a bucket or other open-container shape, such that it has a bottom, side walls, and an open top. In order to provide a thermally insulating barrier to the chamber walls and bottom, the chamber shield may be close and adjacent to, but offset from the chamber walls and bottom. The chamber shield may also have limited contact points with the chamber to reduce thermal conduction to the chamber. In some implementations, a plurality of supports that extend between the chamber bottom and the chamber shield bottom may support the chamber shield in the chamber.

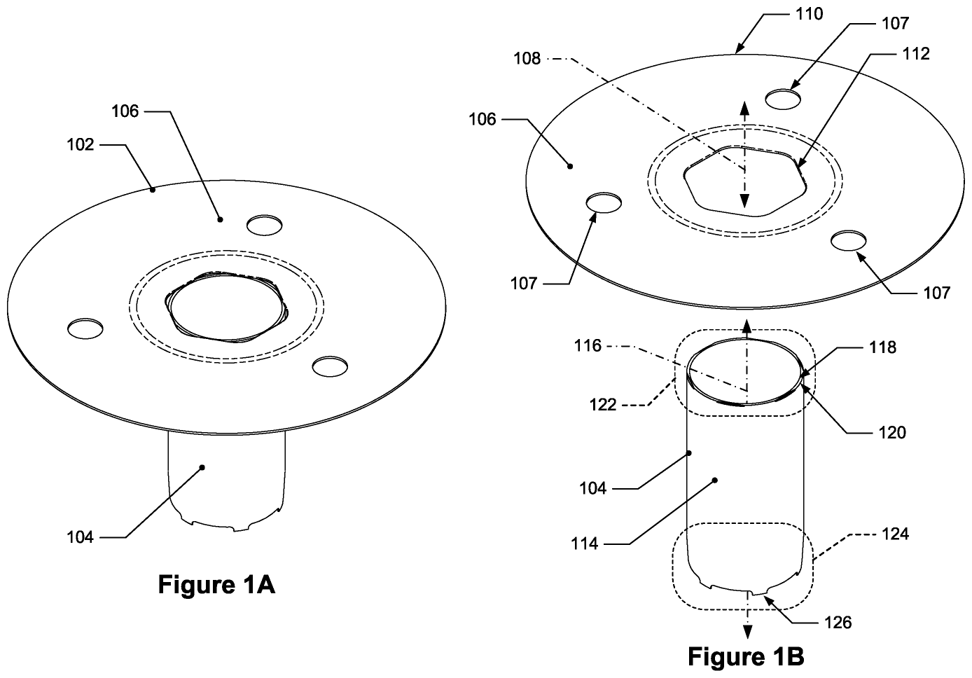

Various features of the thermal shield and collar will now be discussed. FIG. 1A depicts an off-angle view of a thermal shield positioned on a thermal shield collar and FIG. 1B depicts an exploded view of FIG. 1A. The thermal shield 102 in FIG. 1A is positioned on a top region of the thermal shield collar 104. As seen in these Figures, the thermal shield 102 has a body 106 with a substantially annular or ring-like shape that extends around a center axis 108. The body 106 also includes three holes 107 through which lift pins may extend. In FIG. 1B, the body 106 is at least partially defined by an outermost circumferential boundary 110 and an innermost boundary 112 that both extend around the center axis 108.

In some implementations, the shape of the thermal shield 102 body 106 may be considered substantially annular or substantially ring-like because the innermost boundary 112, as illustrated in FIG. 1B, may not be circular and may instead have other shapes, such as various rounded shapes like an ellipse, oval, or obround shape, as well as geometric shapes with linear sections, like a triangle, square, rectangle, pentagon, hexagon, or octagon, for instance, that may have rounded corners between the linear sections. For example, as seen in FIG. 1B, the innermost boundary 112 has a hexagonal shape with rounded corners between each linear section when viewed along the center axis 108. In another example, not depicted, the inner most boundary may be a triangle, square, rectangle, or circular when viewed along the center axis. Further, the innermost boundary 112 may have a plurality of surfaces and in some implementations, these surfaces may not be axisymmetric about the center axis. As explained in greater detail below, the shape of the innermost boundary 112 may be configured to increase thermal resistance and/or to reduce thermal contact with the thermal shield collar 104.

In some implementations, the body 106 of the thermal shield 102 may also be described as a disk with a through-hole that has one or more sides, or described as a flange. The disk may have the outermost circumferential boundary 110 that is circular, and the innermost boundary 112 that bounds the through-hole. The through-hole, and therefore the innermost boundary 112, may have various shapes like the hexagon seen in FIG. 1B, as well as various rounded shapes like an ellipse, oval, or obround shape, and other geometric shapes with linear sections, like a triangle, square, rectangle, pentagon, hexagon, octagon, that may have rounded corners between lines.

The outermost circumferential boundary 110 may be considered circular or substantially circular such that it is not exactly circular due to manufacturing tolerances or inconsistencies. In some instances, the outer boundary may not be circular, but may be another shape, such as an ellipse, oval, or obround shape, and other geometric shapes with linear sections, like a triangle, square, rectangle, pentagon, hexagon, octagon, that may have rounded corners between lines. As discussed below, a circular or substantially circular outer boundary may be advantageous, in some instances, for substantially matching the shape of the underside of the pedestal to increase the view factor between the thermal shield and the pedestal, and to reduce the thermal shield's thermal mass.

In FIG. 1B, the thermal shield collar 104, i.e., the collar 104, has a tubular shaped collar body 114 that extends along a second center axis 116 and is at least partially defined by an inner-circumferential boundary 118 and an outer-circumferential boundary 120 that both extend around the second center axis 116. The collar 104 includes a top region 122 that includes one or more mating surfaces for contacting and supporting the thermal shield 102, and a bottom region 124 that includes one or more feet 126 that each include a support surface, that has a surface area, for contacting a support structure in the processing chamber and supporting the collar 104. These features are described in more detail below.

Various features of the thermal shield 102 will now be discussed. As provided above, the thermal shield 102 is positioned and shaped to have a high view factor with respect to the pedestal in order to receive thermal radiation from the pedestal. In general, a view factor is a number between zero and one that represents a ratio of how much thermal radiation is transferred from one component to another component. When the view factor is one, the one component only “sees” the other component such that the one component receives all thermal radiation from the other component. One example is a sphere within a box; the sphere's view factor is one because it only sees the box and no other item. Here, it is desirable to position and configure the thermal shield so it has a high view factor with respect to the pedestal in order for the thermal shield to receive the pedestal's thermal radiation. The present inventors discovered that this view factor is affected by the spacing between the thermal shield and the pedestal, and by the size of the thermal shield.

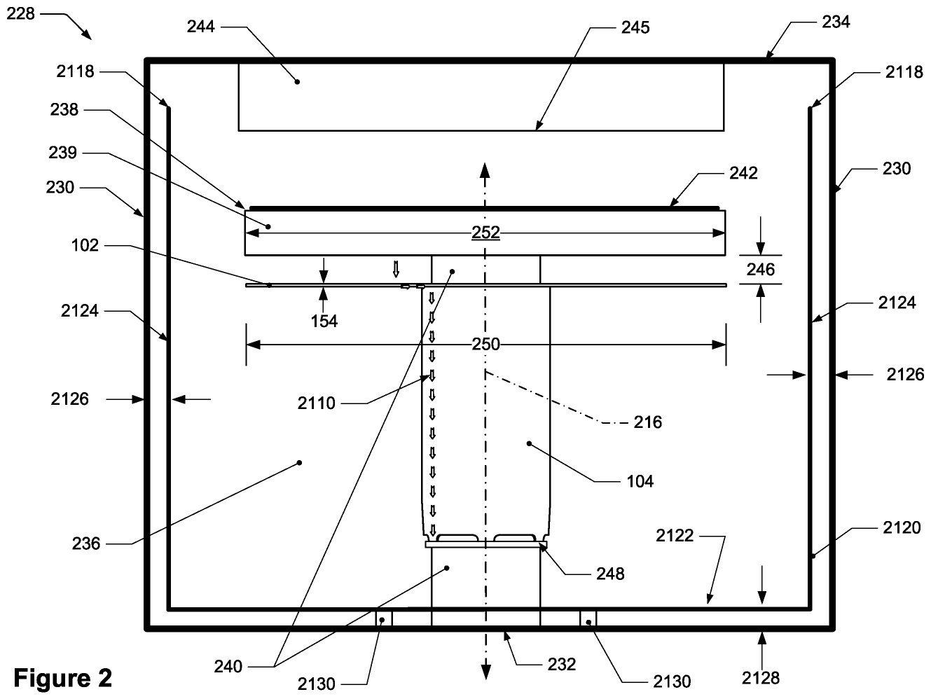

The thermal shield's configuration, positioning, and view factor are further illustrated in FIG. 2 which depicts an example processing chamber schematic. This processing chamber 228 includes chamber walls 230, a chamber bottom 232, and a chamber top 234 that together define a chamber interior 236. A pedestal 238 is positioned within the chamber interior 236 and includes a pedestal base 239 on top of a support column 240. The pedestal base 239 includes a surface for supporting a substrate 242 and one or more heating elements (not pictured), such as resistive heaters, configured to generate heat and heat the substrate 242 to temperatures above 500° C., above 550° C., above 600° C., and above 650° C., for example. The chamber 228 also includes a showerhead 244 or other gas delivery device for delivering process gases onto the substrate 242.

The thermal shield 102 in FIG. 2 is positioned underneath and vertically offset along an axis 216 from the pedestal base 239 by a first offset distance 246. This axis 216 may be collinear with the center axis 108 of the thermal shield, a center axis of the support column, and/or a center axis of the pedestal. The thermal shield 102 is also positioned on and supported by the collar 104, and the collar 104 is positioned around, or encircling, a section of the support column 240 such that the support column 240 extends through the collar 104. The collar 104 is positioned on and supported by a support structure 248 that may be directly or indirectly connected to the support column 240. In some implementations, the thermal shield does not contact any other structure or component except the collar 104, and/or the collar 104 does not contact any other component except the thermal shield 102 and the support structure 248.

The view factor of the thermal shield 102 with respect to the pedestal base 239 is affected by the offset between the two components such that the view factor increases as the first offset distance 246 decreases, and conversely, the view factor decreases as the first offset distance 246 increases. As used herein, unless otherwise specified, the “view factor” is the view factor of the thermal shield with respect to the pedestal base. The present inventors discovered that if the first offset distance 246 is too large, then the view factor becomes too small and the thermal shield 102 becomes less and less effective. In some implementations, it is therefore desirable to have the first offset distance 246 less than or equal to about 2 inches, about 1.75 inches, about 1.5 inches, about 1.25 inches, about 1 inch, about 0.5 inches, about 0.25 inches, about or about 0.1 inches.

It was further discovered that if the first offset distance 246 is too small, then the thermal shield can become undesirably conductively coupled to the pedestal. In some implementations, one or more gases may flow between the thermal shield 102 and the pedestal base 239. These gases may be conductive gases which form a thermally conductive pathway between the pedestal base 239 and the thermal shield 102 across small gaps. It is undesirable to conductively couple the pedestal base 239 and the thermal shield 102 because this results in more unwanted heat loss from the pedestal and the thermal shield no longer acts as a thermal insulator, but instead acts as an unwanted thermal drain. Because of this, it is desirable to have the first offset distance 246 greater than or equal to about 0.1 inches, about 0.15 inches, or about 0.2 inches.

The size and shape of the thermal shield also affects the view factor with respect to the pedestal base. As illustrated in FIG. 2, the thermal shield 102 has an outer shield diameter 250 and the pedestal base 239 has an outer pedestal diameter 252. As the outer shield diameter 250 decreases, the view factor also decreases, with a larger decrease occurring once the outer shield diameter 250 is less than the outer pedestal diameter 252. Conversely, as the outer shield diameter 250 increases, the view factor also increases. However, a competing consideration with the outer shield diameter 250 is the thermal mass of the thermal shield because as the outer shield diameter 250 increases, the thermal shield's thermal mass undesirably increases. As provided herein, it is desirable for the thermal shield to have a small thermal mass to prevent it from draining too much heat from the pedestal and to increase the thermal shield's thermal resistance to therefore reduce its heat transfer to other components.

Due to these considerations, it is desirable in some implementations to have the outer shield diameter 250 be the same, or substantially the same, as the outer pedestal diameter 252 as illustrated in FIG. 2. At this sizing, the view factor is relatively high and the thermal shield's thermal mass is relatively low. In some embodiments, the outer shield diameter may be between about 16 inches and about 12 inches, including about 13 inches, about 13.25 inches, about 13.5 inches, about 13.75 inches, about 14 inches, about 14.25 inches, about 14.5 inches, about 14.75 inches, about 15 inches, about 15.25 inches, about 15.5 inches, or about 15.75 inches.

The outer shape of the thermal shield may also affect the view factor. Some implementations may have the outer shape of the thermal shield match, or substantially match, the outer shape of the pedestal base in order to maximize the view factor while also decreasing the thermal shield's thermal mass. For example, if the outer shapes of the pedestal base and the thermal shield do not match, then the view factor may be higher but the thermal mass will also be undesirably higher, or the thermal mass may be lower but the view factor may be undesirably lower. For instance, if the outer shape of the pedestal base is a circle, and the thermal shield outer shape is an oval with a larger diameter than the circle, then the view factor may be higher, but the thermal mass is also lower. Accordingly, the thermal shield 102 may have a circular or substantially circular outer boundary 110 in some instances that at least substantially matches the shape of the underside of the pedestal to increase the view factor and reduce the thermal shield's thermal mass.

As provided above, it is also desirable to configure the thermal shield with a relatively small thermal mass to increase the thermal shield's thermal resistance and therefore reduce its heat transfer to other components. One manner to accomplish this is to configure the thermal shield with a relatively small thickness. This thickness may be considered a thickness along or parallel to the center axis 108 as illustrated in FIGS. 1B and as labeled item 154 in FIG. 2. This thickness may include a thickness close to, or at, manufacturing tolerances for the thermal shield's material, such as a ceramic. In some embodiments, the thermal shield thickness in a direction parallel to its center axis may be between about 0.01 inches and about 0.5 inches, including about 0.02 inches, about 0.03 inches, about 0.04 inches, about 0.05 inches, about 0.06 inches, about 0.07 inches, about 0.08 inches, about 0.09 inches, about 0.1 inches, about 0.11 inches, about 0.12 inches, about 0.13 inches, about 0.14 inches, about 0.15 inches, about 0.16 inches, about 0.17 inches, about 0.18, about 0.19 inches, about 0.2 inches, about 0.25 inches, about 0.3 inches, about 0.35 inches, about 0.4 inches, about 0.45 inches, or about 0.5 inches.

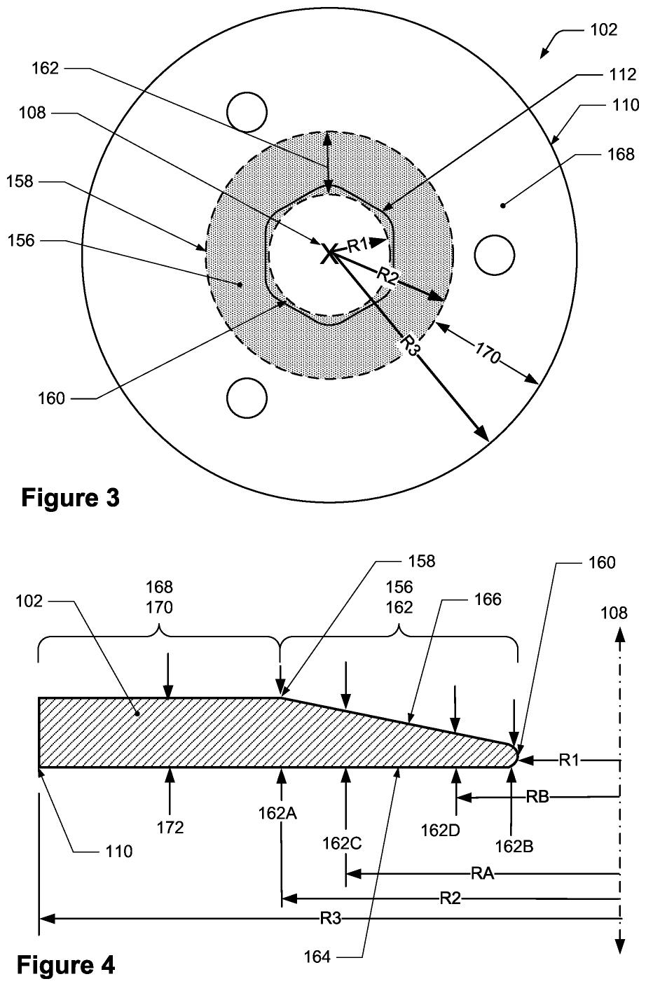

In some implementations, the thermal mass of the thermal shield may be reduced and the thermal resistance may be increased by configuring the thermal shield with a region having a tapered, decreasing thickness. This region may include the area where the thermal shield contacts the collar to further reduce the thermal contact with and thermal conduction to the collar. This region may be represented as an annular region as illustrated in FIG. 3 which depicts a top view of the thermal shield of FIG. 1A. Here, the thermal shield 102 includes an annular region 156, shown with shading and dashed line boundaries, that extends around the center axis 108, shown with an “X”, and includes an outer circumferential boundary 158, an inner boundary 160, and a radial width 162 (which may also be considered a radial thickness) spanning between the outer circumferential boundary 158 and the inner boundary 160 in a direction perpendicular to the center axis 108. The inner boundary 160 may be positioned at a first radial distance R1 from the center axis 108, the outer circumferential boundary 158 may be positioned at a second radial distance R2 from the center axis 108, and the radial width 162 is the difference in these radial distances.

In some embodiments, the region may not be fully annular such that the inner boundary, like the innermost boundary of the thermal shield, may have a non-circular shape. For example, the region may have the same shape as the innermost boundary 112 of the thermal shield 102. In another instance, as illustrated in FIG. 3, the inner boundary 160 may be represented as a circle that represents an average nominal radius, boundary, or circumference. In some such instances, the inner boundary of the region may have the same shape as the innermost boundary of the thermal shield and may overlap with the innermost boundary. The inner boundary may be considered the average nominal radius of the region's actual shape that may be non-circular. In some other embodiments, the inner boundary of the region may be radially offset farther away from the center axis than the innermost boundary.

The thickness of the annular region decreases as the radial distance decreases. FIG. 4 depicts a representative cross-sectional side view slice of one half of the thermal shield of FIG. 3. The slice of FIG. 4 is taken along the center axis of the thermal shield; FIG. 4 is not to scale and is used to illustrate various concepts. A radial section of the annular region 156 is seen with its outer circumferential boundary 158 at a radial distance R2 from the center axis 108 and the inner boundary 160 at a radial distance R1 from the center axis 108. The thickness 162A of the annular region 156, in the direction parallel to the center axis 108, is larger at the outer circumferential boundary 158 than the thickness 162B at the inner boundary 160 and is tapered such that it decreases as the radial distance from the center axis 108 decreases. Additionally, for example, thickness 162C at radial distance RA is less than thickness 162A, but greater than thickness 162B; thickness 162D at radial distance RB is less than thicknesses 162A and 162C, but greater than thickness 162B. In some embodiments, the radial thickness 162A at the outer circumferential boundary 158 may range between about 0.01 inches and about 0.5 inches as provided above, including, for example, about 0.02 inches, about 0.03 inches, about 0.04 inches, about 0.05 inches, about 0.1 inches, about 0.2 inches, or about 0.3 inches, and the thickness 162B at the inner boundary 160 may range between about 0.01 inches and about 0.5 inches as provided above, including, for example, about 0.02 inches, about 0.03 inches, about 0.04 inches, about 0.05 inches, about 0.1 inches, about 0.2 inches, or about 0.3 inches. This region's thickness in a direction parallel to the center axis 108 may also be considered to decrease along the radial width 162 as the radial width 162 decreases and/or to decrease as a function of proximity to the center axis such that the more proximate to (i.e., the closer to) the center axis, the smaller the thickness becomes.

The tapering of the annular region is also configured such that the bottom surface 164 of the thermal shield is substantially perpendicular to the center axis 108 while the top surface 166 is offset at an acute angle from the center axis 108. Having the bottom surface 164 substantially perpendicular may be advantageous for manufacturing purposes and for contacting and being supporting by the collar.

In some implementations, the thickness of the annular region may decrease in other manners. For instance, the tapering illustrated in FIG. 4 is a smooth, linear slope, but in some other implementations, the thickness may decrease in a non-linear manner, such as a curved (e.g., a concave curve or parabolic shape) or a stepped fashion. In some implementations, the thermal shield may not have a region with decreasing thickness and instead may have a substantially constant thickness throughout the shield.

In some embodiments, the thermal shield may have another annular region that has a thickness parallel to the center axis that remains substantially constant throughout the region. Referring back to FIG. 3, this other annular region 168 may be positioned radially offset from and around the annular region 156 such that the annular region 156 is positioned radially inwards from the annular region 168. In some instances, annular region 168 may span between the outer circumferential boundary 158 of the annular region 156 and the outermost boundary 110 of the thermal shield 102 as shown in FIG. 3. The annular region 168 may have a radial width 170 that spans between radial distance R2 and R3 in FIG. 3. This thickness 172 of annular region 168 in a direction parallel to the center axis 108 may be substantially constant along the region's radial width 170 as illustrated in FIG. 4. In some embodiments, the radial thickness 172 may range between about 0.01 inches and about 0.5 inches as provided above, including, for example, about 0.03 inches, about 0.04 inches, about 0.05 inches, about 0.1 inches, about 0.2 inches, or about 0.3 inches, including less than or equal to about 0.5 inches.

The thermal shield may have a composition of one or more thermally insulative materials. Such materials may have a low thermal conduction and/or thermal radiation. Examples include a ceramic, such as an aluminum oxide, as well as an aluminum, an aluminum alloy, a nickel, a nickel alloy, an aluminum nitride, and a silicon oxide. In some implementations, the thermal shield may have a surface treatment or coating provided thereon, such as a treatment to make a silicon oxide, e.g., quartz, opaque to make it a thermal insulator and radiation shield.

In some implementations, the thermal shield composition may also have a relatively low emissivity, and thus a relatively higher reflectivity. This may be advantageous for reducing the thermal shield's emission of the thermal energy to other components and also reflecting thermal energy back to the pedestal and reduce the pedestal's heat loss. The thermal shield's low emissivity may result by one or more surface treatments, such as treating it with nickel, cobalt, aluminum, or aluminum oxide.

As provided above, it is desirable to reduce the heat transfer from the thermal shield to any other component in the processing chamber, including the collar, in order for the thermal shield to act as a thermal insulator and retain the heat radiatively received from the pedestal. While it is not possible to completely thermally isolate and float the thermal shield in the processing chamber, the thermal shield and the thermal shield's supporting structure, the collar, are configured to provide significant thermal isolation between the thermal shield and other components. In some implementations, the thermal shield does not physically contact any other component in the processing chamber except for the collar, thereby limiting is physical conductive heat transfer to the collar. Conductive heat transfer from the thermal shield to the collar may be reduced by increasing the contact resistance through minimizing the contact surface area between the components and increasing the thermal resistance of the collar.

Further, having the thermal shield and the collar as separate structures provides additional benefits to reducing heat transfer from the thermal shield to other components. As separate structures, the thermal conduction between the thermal shield and the collar is less than if the thermal shield and the collar were a single, unitary structure. Additionally, the thermal stress between the components, and resulting damage, are less, or non-existent, as separate structures than as a single body. Further, having the two as separate structures allow for thermal expansion between the two parts.

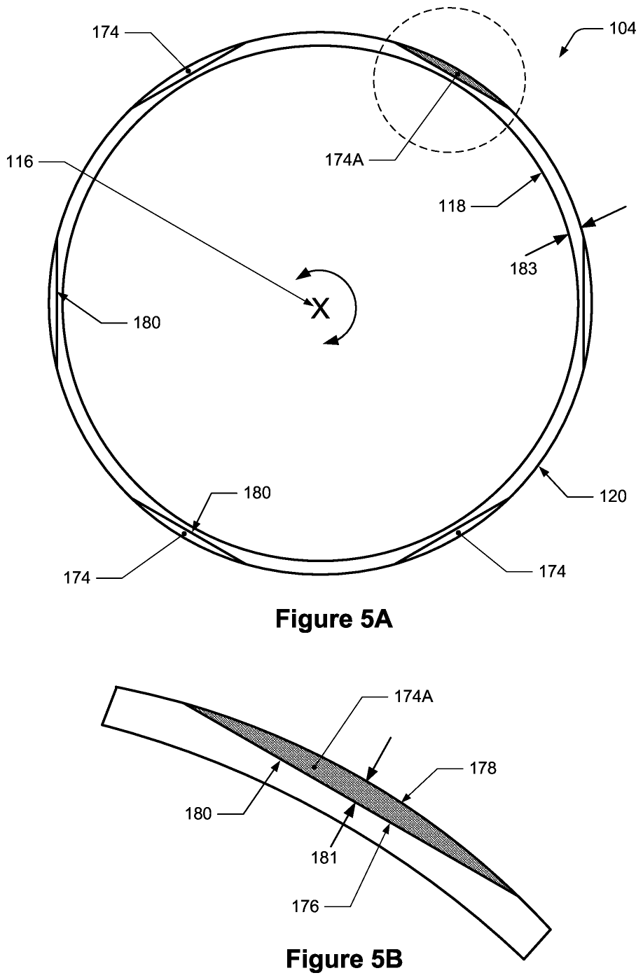

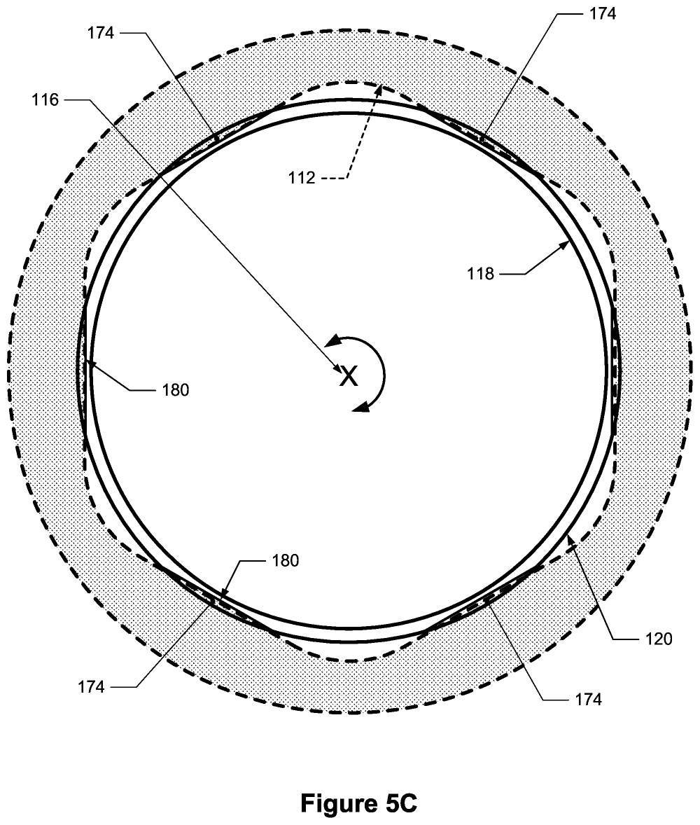

The contact interface between the thermal shield and the collar may be between various surfaces of both components. For example, the collar may include one or more mating surfaces configured to contact and interface with the thermal shield. The one or more mating surfaces may contact the bottom surface of the thermal shield and provide vertical support to the thermal shield. In some implementations, the mating surface may be a single annular mating surface, such as a ring, that extends around the center axis of the collar. In some other implementations, the collar may include a plurality of mating surfaces that provide minimal contact with the thermal shield. FIG. 5A depicts a top view of the thermal shield collar of FIGS. 1A and 1B. As can be seen, the collar 104 has a tubular shape with the inner-circumferential boundary 118 and the outer-circumferential boundary 120 both extending around the center axis 116 (shown as an “X”).

In the visible top region of the collar 104 in FIG. 5A, the collar 104 includes six mating surfaces 174, four of which are identified, and one 174A is highlighted with shading. These mating surfaces 174 are separate from each other and arranged around the center axis 116 at substantially equal spacing to each other. In some instances, these mating surfaces 174 may be arranged in a circular array around the collar center axis. Each mating surface 174 also has the shape of a segment that is defined by a chord and an arc, or an arc and a line joining the end points of that arc. One segment is enlarged in FIG. 5B which depicts a magnified view of one mating surface in FIG. 5A. Here, mating surface 174A is a segment defined by a chord 176 and an arc 178 that is radially outwards from the chord 176 and the center axis 116 (not shown in FIG. 5B). By using the plurality of separate mating surfaces, a limited contact surface area is provided to the thermal shield thereby limiting thermal conduction from the thermal shield to the collar 104 to these small areas.

In some embodiments, the maximum radial thickness 181 of each mating surface 174 may be less than or equal to 2.5 mm, 2 mm, 1.5 mm, or 1 mm, for instance. In some implementations, the total area of each mating surface 174 may be less than or equal to about 0.25 square inches, about 0.225 square inches, about 0.2 square inches, bout 0.175 square inches, about 0.15 square inches, about 0.125 square inches, about 0.1 square inches, about 0.080 square inches, about 0.075 square inches, about 0.060 square inches, about 0.050 square inches, about 0.045 square inches, about 0.040 square inches, about 0.030 square inches, about 0.025 square inches, or about 0.02 square inches, for example. It has been found that these dimensions, at least in part, result in a significant reduction of thermal conduction from the thermal shield to the collar.

The collar may also include one or more constraint surfaces that are configured to prevent, or at least limit, potential rotation and/or radial movement of the thermal shield. In the visible top region of the collar 104 in FIG. 5A, the collar 104 includes a plurality of constraint surfaces 180 that may intersect or overlap with the mating surfaces when viewed along center axis 116 as shown in FIG. 5A. Here, the constraint surfaces 180, two of which are identified, overlap with the chords 176 of each mating surface. When a thermal shield is positioned on the mating surfaces 174 of the collar 104, the constraint surfaces 180 reduce or prevent the thermal shield from moving radially with respect to the center axis 116 of the collar. The configuration of the constraint surfaces 180 of FIG. 5A also reduce or prevent the thermal shield from rotating about the center axis 116 of the collar 104; this rotation is represented by the double arrow extending partially around the center axis 116.

In a further illustration, a top view of the collar of FIG. 5A and a portion of a thermal shield positioned thereon is seen in FIG. 5C. The portion of the thermal shield 102 is illustrated with dashed line boundaries and transparent light shading such that the collar 104 underneath is visible. The thermal shield 102 is positioned on the collar 104 and the two components are in contact at the collar's mating surfaces 174 and constraint surfaces 180. The shape of the innermost boundary 112 of the thermal shield 102 and the positioning and shape of the mating surfaces 174 of the collar 104 enable the thermal shield to be aligned on the collar 104. This alignment allows the thermal shield 102 to be positioned at a known orientation and location with respect to the collar 104 and/or pedestal which may align the holes 107 of the thermal shield 102 with the lift pins in multiple positions thereby making installation of these components easier and more efficient.

In some implementations of this positioning, as illustrated in FIG. 5C, the center axis of the thermal shield and the center axis of the collar are collinear, or substantially collinear. The configuration of the collar's mating surfaces 174 and constraint surfaces 180 also limit the surface contact between the collar 104 and the thermal shield 102 and therefore reduce the thermal conduction between the two components. The configuration of the collar's constraint surfaces 180 also prevent the thermal shield's radial movement and rotation around the center axis 116 of the collar 104. Without these constraint surfaces, repeated vertical movement of the pedestal can cause the thermal shield to rotate and cause it to become misaligned with the pedestal and thus not function properly, and/or cause the holes 107 to become misaligned with the lift pins which can prevent the lift pins from functioning properly.

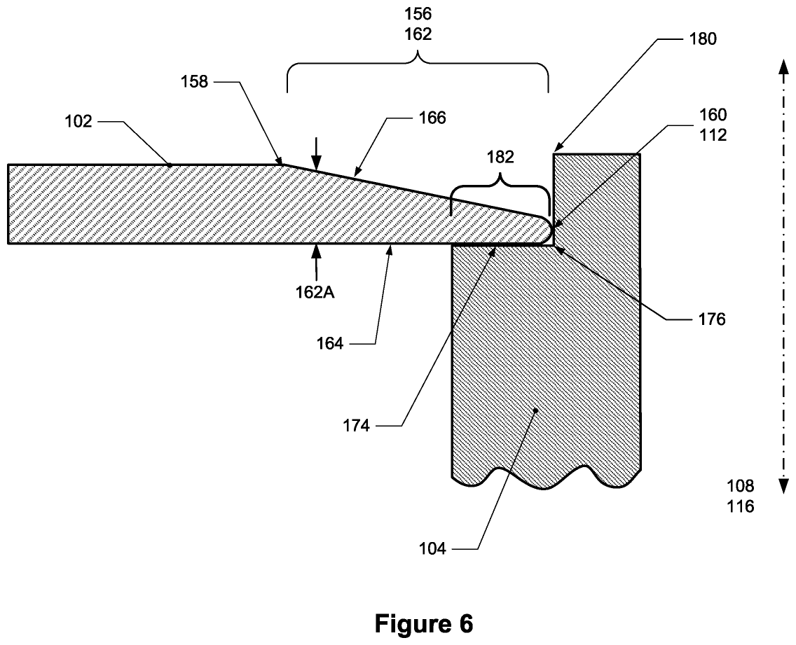

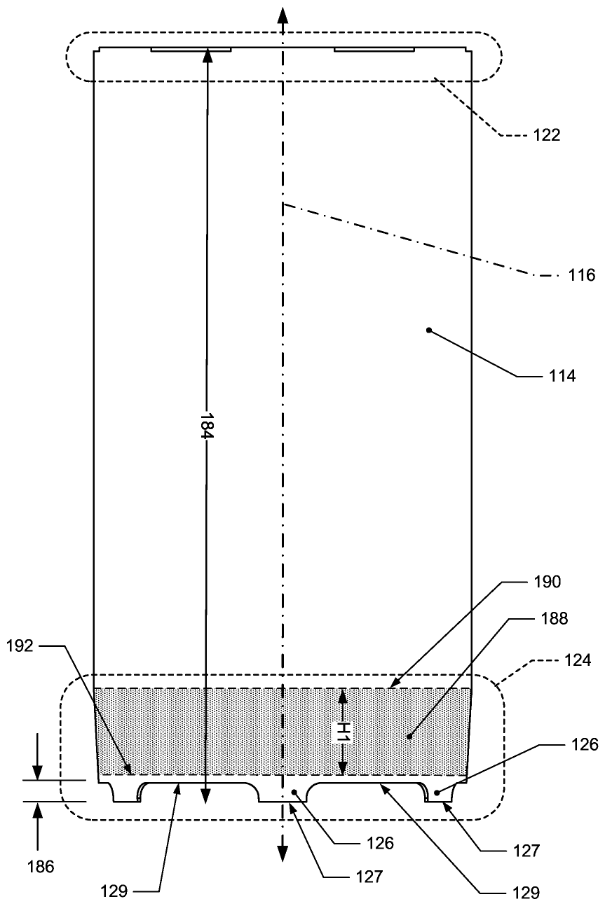

The contact between the thermal shield and collar is further illustrated in FIG. 6 which depicts a representational, magnified cross-sectional side view slice of the thermal shield of FIG. 4 and a part of a thermal shield collar. This illustrative view is taken along the collinear center axes of the collar and thermal shield, and is not to scale; it is oriented perpendicular to the center axis and depicts portions of the collar and the thermal shield to the left of the center axis. Some features of the thermal shield 102 are identified, including the outer circumferential boundary 158, the inner boundary 160, and the decreasing radial width 162 of the annular region 156. The thermal shield 102 also includes one or more shield mating surfaces that are configured to be in contact with the collar. Here, a portion of the bottom surface 164 of the thermal shield 102, which may be considered the shield mating surface 182, is in contact with a mating surface 174 of the collar 104.

One constraint surface 180 is illustrated in FIG. 6 and is seen extending along the center axis 116 of the collar 104. In some implementations, the constraint surface 180 may be oriented at a substantially perpendicular angle to the contact surface and/or may be oriented at a substantially parallel angle to the center axis 116. In some instances, the angle between the constraint surface 180 and the mating surface 174 may be acute or obtuse, and the constraint surface 180 may face away from the center axis and/or may have a directional component that is parallel to the center axis 116. As further illustrated, the constraint surface 180 may also intersect with and be partially defined by the corresponding mating surface 174, such as the chord 176. The constraint surface 180 is also configured such that it prevents, or reduces, movement of the thermal shield radially with respect to the center axis 116 of the collar 104. This configuration includes positioning it radially inwards of the innermost boundary 112 and/or the inner boundary of the annular region 156 of the thermal shield 102 when the thermal shield 102 is positioned on the collar 104.

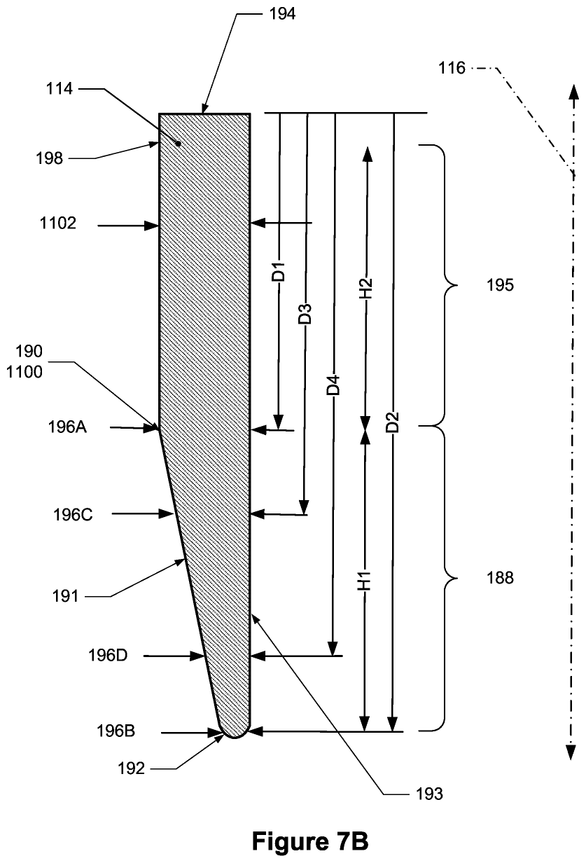

Additional or alternative features of the collar will now be discussed. The collar may be configured to reduce its thermal conduction to the support structure on which it is positioned. This configuration may include increasing the thermal resistance of its body and/or limiting its contact surface area with the support structure. FIG. 7A depicts a side view of the collar of FIGS. 1A and 1B. The collar 104 has the collar body 114 with a length 184 that extends along its center axis 116. To reduce thermal conduction between the collar 104 and the support structure, the collar may have features that provide limited contact surface area with the support structure and thereby increases the thermal resistance between the two components.

In FIG. 7A, these features include one or more feet 126 in the bottom region 124 that each include a support surface 127 for contacting the support structure 248 in the processing chamber and for supporting the collar 104. The feet 126 may, in some instances, be considered crenellations or castellations. The collar body 114 includes a bottom surface 129 in the bottom region 124 and the feet 126 extend away from the bottom surface 129 along the center axis 116 by a second offset distance 186 such that each support surface 127 is offset from the bottom surface 129 by the second offset distance 186. The bottom surface 129 is therefore positioned along the center axis 116 between the support surface 127 and the top region 122. Using these offset feet decreases the surface area of the collar where it contacts the support structure thereby reducing the thermal conduction between these components. In some implementations, the surface area of each support surface 127 of each foot 126 may be less than or equal to about 0.2 square inches, about 0.175 square inches, about 0.15 square inches, about 0.125 square inches, about 0.1 square inches, about 0.075 square inches, about 0.05 square inches, about 0.040 square inches, about 0.030 square inches, about 0.020 square inches, about 0.010 square inches, about 0.009 square inches, about 0.008 square inches, 0.0075 square inches, or about 0.005 square inches, for example.

Reducing the thermal conduction through the collar may also include reducing its thermal mass and/or having a tapered or decreasing radial thickness. Referring back to FIG. 5A, the tubular shape of the collar body 114 may have a small radial thickness 183, or cross-sectional area, in a direction perpendicular to the center axis 116. In some embodiments, the radial thickness 183 may be between about 0.01 inches and about 0.5 inches, including about 0.02 inches, about 0.03 inches, about 0.04 inches, about 0.05 inches, about 0.06 inches, about 0.07 inches, about 0.08 inches, about 0.09 inches, about 0.1 inches, about 0.11 inches, about 0.12 inches, about 0.13 inches, about 0.14 inches, about 0.15 inches, about 0.16 inches, about 0.17 inches, about 0.18, about 0.19 inches, about 0.2 inches, about 0.25 inches, about 0.3 inches, about 0.35 inches, about 0.4 inches, about 0.45 inches, or about 0.5 inches. Similar to the radial shield, the collar may have a region with a varying or tapered thickness, such as a decreasing radial thickness or cross-sectional area, as the distance away from the top region 122 along the center axis increases, or as the distance towards the support surface 127 along the center axis decreases.

In FIG. 7A, the collar body 114 includes a tubular region 188, highlighted with shading, that extends around the center axis 116 and has a decreasing or tapered thickness. The region 188 is at least partially defined by a first top circumferential boundary 190 and a first bottom circumferential boundary 192 offset from the first top circumferential boundary by a first height H1 along the length of the collar body 114. In a direction perpendicular to the center axis 116, the region 188 has a tapered thickness along the first height that decreases as the distance from the top region 122 increases. As shown in FIG. 7A, the tubular region may be in the bottom region 124 of the collar body 114.

In some implementations, the first bottom circumferential boundary 192 may be positioned at a different location than shown in FIG. 7A, such as coincident with the bottom surface 129 or the support surface 127. The feet 126 may therefore also have a tapered for decreasing radial thickness along their second offset distance 186 as the distance away from the top region 122 increases. In some embodiments, the first top circumferential boundary 190 may also be positioned in a different location than depicted in FIG. 7A, such as in the top region 122.

The tapered thickness of region 188 is further illustrated with FIG. 7B which depicts a representative cross-sectional side view slice of a portion of the thermal shield collar of FIG. 7A. The slice of FIG. 7B is taken along the center axis of the collar; FIG. 7B is not to scale and is used to illustrate various concepts. The tubular region 188 is seen with its first top circumferential boundary 190 at a first longitudinal offset distance D1 along the center axis 116 from the top surface 194 of the collar body 114, and the first bottom circumferential boundary 192 at the second longitudinal offset distance D2 along the center axis 116 from the top surface 194. The first bottom circumferential boundary 192 is farther from the top surface 194 than the first top circumferential boundary 190, such that D2 is greater than D1.

The thickness 196A of the tubular region 188 in the direction perpendicular to the center axis 116 is larger at the first top circumferential boundary 190 than the thickness 196B at the first bottom circumferential boundary 192 and is tapered such that it decreases as the longitudinal distance along the center axis increases from the top region 122 or from the top surface 194. Additionally, for example, thickness 196C at longitudinal distance D3 is less than thickness 196A, and thickness 196D at longitudinal distance D4 is less than thickness 196C. In some embodiments, the radial thickness 196A at the first top circumferential boundary 190 may range between about 0.01 inches and about 0.5, including, for example, about 0.02 inches, about 0.03 inches, about 0.04 inches, about 0.05 inches, about 0.1 inches, about 0.2 inches, or about 0.3 inches, and the radial thickness 196B at the first bottom circumferential boundary 192 may range between about 0.01 inches and about 0.5 inches, including, for example, about 0.02 inches, about 0.03 inches, about 0.04 inches, about 0.05 inches, about 0.1 inches, about 0.2 inches, or about 0.3 inches. This region's radial thickness in a direction perpendicular to the center axis 116 may also be considered to decrease along the center axis 116 as the longitudinal distance from the top surface 194 increases.

The tapering of the annular region may also be configured such that inner surface 191 of the collar is substantially perpendicular to the center axis 116 while the outer surface 193 is offset at an acute angle from the center axis 116. Having this shape may be advantageous for various purposes including manufacturing ease and efficiency. In some implementations, positioning the tapering on the outside of the part, such as the collar or the thermal shield, enables the part to be self-centered with respect to the supporting structure, e.g., the support column or collar.

The thickness of the tubular region may decrease in various manners to increase the thermal resistance in this region. For instance, the radial thickness decrease may be a smooth, linear slope as shown in FIG. 7B, or it may be non-linear, such as a curve (e.g., a concave curve or parabolic shape) or stepped decrease.

As mentioned above, the decreasing radial thickness and a minimal contact area with a supporting surface, whether individually or together, reduce the heat conducted from the collar to the component or components directly supporting the collar and indirectly supporting the thermal shield. As mentioned above, referring back to FIG. 2, in some implementations the feet 126 of the collar 104 are supported by a single support surface or structure 248 that is connected to the support column 240 of the pedestal. By reducing the heat transferred to other components, including the support structure 248 and support column 240, the collar 104 and thermal shield 102 are able to act as thermal insulators to the processing chamber and pedestal.

In some embodiments, the collar may have another tubular region that has a thickness perpendicular to the center axis that remains substantially constant throughout the region. In FIG. 7B, this other tubular region 195 may be positioned offset from and above the tubular region 188 such that the other tubular region 195 is closer to or overlapping with the top region 122 or top surface 194. In some instances, the tubular region 195 may have a second top circumferential boundary 198 and a second bottom circumferential boundary 1100 that may overlap with the first top circumferential boundary 190 of the tubular region 188. The other tubular region 195 may have a height H2 along the center axis 116 and a radial thickness 1102 in a direction perpendicular to the center axis 116 that may be substantially constant as illustrated in FIG. 7B. In some embodiments, the radial thickness 1102 may range about 0.01 inches and about 0.5 inches as provided above, including, for example, about 0.03 inches, about 0.04 inches, about 0.05 inches, about 0.1 inches, about 0.2 inches, or about 0.3 inches, including less than or equal to about 0.5 inches.

Similar to the thermal shield, the thermal collar may have a composition of one or more thermally insulative materials. Such materials may have a low thermal conduction and/or thermal radiation. Examples include a ceramic, such as an aluminum oxide, as well as an aluminum, an aluminum alloy, a nickel, a nickel alloy, an aluminum nitride, and a silicon oxide. In some implementations, the collar may have a surface treatment or coating provided thereon, such as a treatment to make a silicon oxide, e.g., quartz, opaque to make it a thermal insulator and radiation shield.

Similar to the thermal shield, in some implementations the collar's composition may also have a relatively low emissivity, and thus a relatively higher reflectivity. This may be advantageous for reducing the collar's emission of the thermal energy to other components. The collar's low emissivity may result by one or more surface treatments, such as treating it with nickel, cobalt, aluminum, or aluminum oxide.

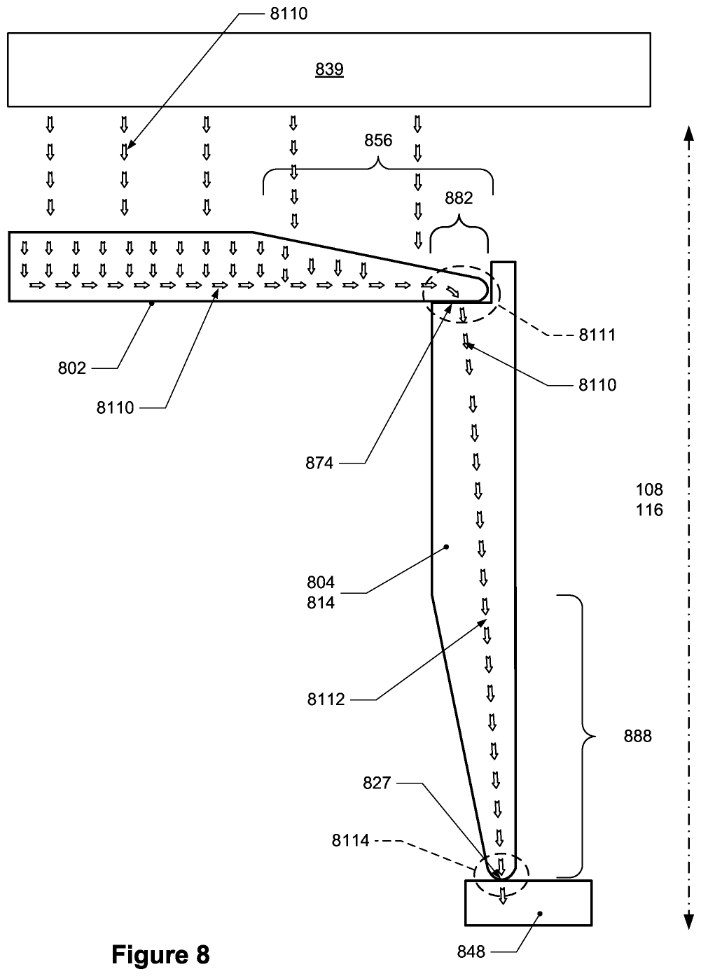

Some of the thermal pathways and considerations are further illustrated in FIGS. 2 and 8. In FIG. 2, the processing chamber 228 includes the pedestal 238 with the pedestal base 239 on the support column 240, and the thermal shield 102 positioned underneath and offset from the pedestal base 239, and on the collar 104. The collar 104 is positioned on and supported by the support structure 248 which may be directly or indirectly connected to the support column 240. Heat radiated by the pedestal 238, represented by white arrows 2110, is absorbed by the thermal shield 102 and some heat is conducted to and through the collar 104, and from the collar 104 to the support structure 248. However, as discussed herein, the thermal shield 102 and collar 104 are configured to reduce the thermal conduction to other structures in the chamber. In some implementations, the thermal shield and the collar may be used independently or together as aspects of a heat shield system in a semiconductor processing chamber. In some such instances, FIGS. 2 and 8 may depict aspects of a heat shield system.

An additional illustration is provided in FIG. 8 which depicts a cross-sectional side view of a representational schematic of a pedestal base, a thermal shield, and a thermal collar. This Figure not to-scale and used for illustration purposes of various concepts; the cross-hatching has also been removed for clarity. Here in FIG. 8, a partial cross-sectional side view of the thermal shield 802 of FIG. 6, a collar 804 similar to that of FIG. 7B, a support surface 848, and a pedestal base 239 of a pedestal are illustrated; these are the same features as in FIG. 2 except for the different scale and other noted differences. The thermal shield 802 is positioned underneath the pedestal base 839 and on the collar 804, as described above with respect to FIG. 6, such that the shield mating surface 882 is on the mating surface 874 of the collar 804. The collar 804 is also positioned on the support surface 848. The pedestal base 839 is shown radiating heat, illustrated by the white arrows 8110, to the thermal shield 802 and this heat is retained by the thermal shield 802, including into and through the annular region 856 of the thermal shield 802 having the decreasing thickness and increased thermal resistance. Due to the limited thermal resistance in the annular region 856, limited heat is conducted through this annular region 856 towards and to the collar 804.

As further illustrated in FIG. 8, some heat is conducted from the thermal shield 802 to the collar 804 in contact area 8111 where the shield mating surface 882 is in contact with the mating surface 874 of the collar 804. This contact area 8111 has a high thermal resistance, so limited heat is conducted from the thermal shield 802 to the collar 804 as still represented by the arrows 8110. The heat conducted to the collar 804 is also conducted through the collar body 814 to the support surface 848. But the thermal resistance through the collar 804, including the cylindrical region 888 with decreasing thickness and increasing thermal resistance, reduces this heat transfer over the length of the collar 804. The thermal resistance at the contact area 8114 between the collar 804 and the support structure 848, where the support surface 827 of the feet contacts the support structure 848, also reduces the thermal conduction between the collar 804 and support structure 848.

In some implementations, the processing chamber may alternatively or additionally include a chamber shield configured to provide thermal insulation between the pedestal and the chamber walls. Referring back to FIG. 2, a chamber shield 2120 is seen in the processing chamber 228 and it includes a bottom 2122 and one or more side walls 2124 extending from the bottom 2122. In some implementations, as seen in FIG. 2, the chamber shield 2120 is positioned adjacent to, but offset from and therefore not in direct contact with, the processing chamber walls 230 and chamber bottom 232. The chamber shield side wall 2124 is offset from the processing chamber side wall 230 by a first chamber offset distance 2126, and the chamber shield bottom 2122 is offset from the chamber bottom 232 by a second chamber offset distance 2128. In some implementations, the first chamber offset distance 2126 and the second chamber offset distance 2128 are the same or substantially the same value, while in other implementations they are different from each other. In some embodiments, the first chamber offset distance 2126 may be between about 0.05 inches and about 2 inches, including about 0.075 inches, about 0.1 inches, about 0.25 inches, about 0.5 inches, about 0.75 inches, about 1 inch, about 1.25 inches, about 1.5 inches, or about 1.75 inches. In some embodiments, the second chamber offset distance 2128 may be between about 0.05 inches and about 2 inches, including about 0.075 inches, about 0.1 inches, about 0.25 inches, about 0.5 inches, about 0.75 inches, about 1 inch, about 1.25 inches, about 1.5 inches, or about 1.75 inches.

The chamber shield may have one or more thicknesses that are configured to reduce its thermal mass. By reducing the chamber shield's thermal mass, it is able to function as thermal insulator. These thicknesses may include, for example, between about 0.01 inches and about 0.5, including, for example, about 0.02 inches, about 0.03 inches, about 0.04 inches, about 0.05 inches, about 0.1 inches, about 0.2 inches, or about 0.3 inches.

The chamber shield may be positioned on and supported by one or more supports. These supports may be in various locations, including on the bottom of the chamber shield as shown in FIG. 2. Here, chamber shield 2120 is positioned on and supported by supports 2130 that are connected to the chamber bottom 232. These supports 2130 span between the chamber shield 2120 and the chamber bottom 232. In some implementations, like depicted in FIG. 2, the chamber shield is not in direct contact with any portion of the processing chamber, such as the chamber walls, the chamber bottom, and the pedestal.

The supports 2130 may also be configured to increase contact resistance between the chamber shield 2120 and other components, such as the chamber sidewalls and bottom. This may include providing thermal insulators between the supports and the components, reducing the number of supports used, and/or configuring the supports 2130 to have a thermally material composition, such as a ceramic or stainless steel.

In some implementations, the top of the chamber shield side wall(s) may extend to various distances with respect to the showerhead. Some pedestals are capable of vertical movement within the chamber. It may be advantageous to position the chamber shield such that it provides thermal insulation to the chamber side walls independent of the pedestal's positioning. Some implementations may therefore have the top of the chamber shield's side wall or walls at at least the same vertical positioning as the bottom surface of the showerhead. In some embodiments, as illustrated in FIG. 2, it may be advantageous to have the top 2118 of the chamber shield's side wall or walls higher than the bottom surface 245 of the showerhead 244. Here, the chamber shield 2120 is positioned to provide thermal insulation to the chamber side walls 230 regardless of the positioning of the pedestal 238 and the showerhead 244. The chamber shield side wall(s) may also be radially offset from and outside the outer surface of the showerhead 244 in order to improve gas flow between the showerhead 244 and the pedestal 238.

In some embodiments, the chamber shield may have a bucket-like shape with a cylindrical side wall and open top, or other open-top style shape with a plurality of side walls. When viewed along a center axis of the chamber shield, the one or more sidewalls may have various shapes, including circular, elliptical, obround, rectangular, square, or other geometric shape like a pentagon, hexagon, octagon, etc.

The chamber shield may have a composition of one or more thermally insulative materials. Such materials may have a low thermal conduction and/or thermal radiation. Examples include a ceramic, such as an aluminum oxide, as well as an aluminum, an aluminum alloy, a nickel, a nickel alloy, an aluminum nitride, and a silicon oxide. In some implementations, the chamber shield may have a surface treatment or coating provided thereon, such as a treatment to make a silicon oxide, e.g., quartz, opaque to make it a thermal insulator and radiation shield.

### Results

Use of the thermal shield and collar provided herein provide significant thermal insulation to the pedestal and chamber. In one experiment, the pedestal base was heated to a temperature above 550° C. and a thermal shield and collar as described herein were used with that pedestal. It was found that the thermal shield had a maximum temperature of approximately 140° C. less than the pedestal base and an overall temperature difference throughout the thermal shield of about 10° C., thereby indicating that the thermal shield absorbed and retained thermal radiation from the pedestal base while providing thermal insulation of this heat. At the contact points between the thermal shield and the collar, the temperature difference between the thermal shield and collar was approximately 145° C., thereby indicating that heat transfer between the thermal shield and collar is significantly reduced. The bottom of the collar where it contacts the support structure directly or indirectly connected to the support column of the pedestal measured about 90° C. less than the collar's contact point with the thermal shield, resulting in a temperature gradient of about 90° C. along the length of the collar. This indicates that the collar is providing significant thermal insulation/resistance to restrict the amount of conduction lost by the shield. Accordingly, the thermal conduction from the thermal shield to the collar's contact area to the support structure was reduced by about 244° C.

The thermal insulation and reduced heat transfer to other components provided by the thermal shield and collar herein was found to adequately protect other components in the processing chamber. Further the use of the thermal shield and collar reduced the overall power loss from using higher pedestal temperatures. For example, it was found that increasing a pedestal temperature of between about 525° C. and about 575° C. by about 100° C., resulted in an additional power loss of about 37%. When the thermal shield and collar were used at the higher temperatures, the overall additional power loss was reduced from 37% to 26%.

It is to be understood that the use of ordinal indicators, e.g., (a), (b), (c), . . . , herein is for organizational purposes only, and is not intended to convey any particular sequence or importance to the items associated with each ordinal indicator. For example, “(a) obtain information regarding velocity and (b) obtain information regarding position” would be inclusive of obtaining information regarding position before obtaining information regarding velocity, obtaining information regarding velocity before obtaining information regarding position, and obtaining information regarding position simultaneously with obtaining information regarding velocity. There may nonetheless be instances in which some items associated with ordinal indicators may inherently require a particular sequence, e.g., “(a) obtain information regarding velocity, (b) determine a first acceleration based on the information regarding velocity, and (c) obtain information regarding position”; in this example, (a) would need to be performed (b) since (b) relies on information obtained in (a)-(c), however, could be performed before or after either of (a) or (b).

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

The term “substantially” herein, unless otherwise specified, means within 5% of the referenced value. For example, substantially perpendicular means within +/−5% of parallel. The term “substantially” may be used herein to indicate that while exactness of measurements and relationships may be intended, exactness is not always achieved or achievable because of manufacturing imperfections and tolerances. For instance, it may be intended to manufacture two separate features to have the same size (e.g., two holes), but because of various manufacturing imperfections, these features may be close to, but not exactly, the same size.

What is claimed is:

1. A thermal shield for use in a semiconductor processing chamber, the thermal shield comprising:
a body having a substantially annular shape that extends around a center axis and that is at least partially defined by an outermost circumferential boundary that ranges between about 12 inches and about 16 inches and an innermost boundary,
wherein:
the body is formed of a ceramic material; and
the body has a thickness that is less than or equal to 0.5 inches.

2. The thermal shield of claim 1, wherein:
the body further includes a first annular region that extends around the center axis, the first annular region having:
an outer circumferential boundary;
an inner boundary;
a radial width spanning between the outer circumferential boundary and the inner boundary in a direction perpendicular to the center axis; and
a first thickness in a direction parallel to the center axis that decreases as a function of proximity to the center axis; and
the first thickness is less than or equal to 0.5 inches.

3. The thermal shield of claim 2, wherein:
at the outer circumferential boundary of the first annular region, the body has an outer first thickness in the direction parallel to the center axis that is between about 0.01 inches and 0.5 inches;
at the inner boundary of the first annular region, the body has an inner first thickness in the direction parallel to the center axis; and
the inner first thickness is less than the outer first thickness and is between about 0.01 inches and 0.5 inches.

4. The thermal shield of claim 2, wherein the radial width of the annular region ranges between about 0.01 inches and 0.5 inches.

5. The thermal shield of claim 1, wherein the body further includes a second annular region that extends around the center axis and has:
a second radial width in a direction perpendicular to the center axis; and
a second thickness in a direction parallel to the center axis that remains substantially constant along the second radial width.

6. The thermal shield of claim 1, wherein the body comprises a plurality of holes configured for lift pins to pass through.

7. A thermal shield collar for use in a semiconductor processing chamber, the thermal collar comprising:
a collar body having a tubular shape with a collar inner circumferential boundary and a collar outer circumferential boundary that both extend around a collar center axis and further having a length that extends along the collar center axis,
wherein the collar body is formed of a ceramic material, and
wherein the collar body comprises:
a top region and a bottom region;
a bottom surface in the bottom region; and
a plurality of feet in the bottom region, each foot having a support surface and each foot extending away from the bottom surface along the collar center axis by at least a first distance such that each support surface is offset from the bottom surface by at least the first distance.

8. The thermal shield collar of claim 7, wherein:
the collar body further comprises a first tubular region that:
extends around the collar center axis;
is at least partially defined by a first collar top circumferential boundary and a first collar bottom circumferential boundary offset from the first collar top circumferential boundary by a first height along the collar center axis of the collar body; and
has a tapered thickness in a direction perpendicular to the collar center axis and along the collar center axis that decreases as the distance from the top region increases; and
the first collar top circumferential boundary is closer to the top region than the first collar bottom circumferential boundary.

9. The thermal shield collar of claim 8, wherein:
at the first collar top circumferential boundary, the collar body has a first collar thickness in the direction perpendicular to the collar center axis; and
at the first collar bottom circumferential boundary, the collar body has a second collar thickness in the direction perpendicular to the collar center axis that is less than the first collar thickness.

10. The thermal shield collar of claim 7, wherein:
the collar body includes a second tubular region positioned in at least the top region and at least partially defined by a second collar top circumferential boundary and a second collar bottom circumferential boundary offset from the second collar top circumferential boundary by a second height along the collar center axis; and
the second tubular region has a third thickness in a direction perpendicular to the collar center axis that remains substantially constant along the collar center axis.

11. The thermal shield collar of claim 7, wherein:
the collar body includes one or more second mating surfaces in the top region that are configured to interface with one or more first mating surfaces of a thermal shield; and
each second mating surface:
is separate from the other mating surfaces; and
has the shape of a segment defined by an arc and a line joining the end points thereof.

12. The thermal shield collar of claim 11, wherein:
the collar body further includes a plurality of constraint surfaces in the top region; and
each constraint surface:
faces away from the collar center axis;
intersects with a corresponding one of the second mating surfaces such that each constraint surface is at least partially defined by the line of the corresponding second mating surface; and
is oriented at a non-parallel angle to the corresponding second mating surface.

13. An apparatus comprising:
a semiconductor processing chamber;
a substrate support configured to support a wafer and having a pedestal base and a support column under the pedestal base;
a thermal shield that includes a body having a substantially annular shape that extends around a center axis and that is at least partially defined by an outermost circumferential boundary that ranges between about 12 inches and about 16 inches and an innermost boundary, wherein the body is formed of a ceramic material, includes one or more first mating surfaces within an annular region adjacent to the innermost boundary, and has a thickness that is less than or equal to 0.5 inches; and
a thermal shield collar having a collar body formed of the ceramic material, the collar body comprising:
a tubular shape with a collar inner circumferential boundary and a collar outer circumferential boundary that both extend around a collar center axis and a length that extends along the collar center axis;
a top region and a bottom region;
one or more support surfaces in the bottom region; and
one or more second mating surfaces in the top region that are configured to interface with the one or more first mating surfaces of the thermal shield,
wherein:
the thermal shield is positioned underneath the pedestal base and offset from a bottom surface of the pedestal base by a first distance that ranges between about 0.1 inches and about 2 inches;
the thermal shield is positioned on and supported by the thermal shield collar;
the center axis and the collar center axis are collinear;
at least a portion of the support column is positioned inside and extends through the thermal shield collar;
the one or more support surfaces are supported by the substrate support; and
the one or more first mating surfaces are in contact with the one or more second mating surfaces.

14. The apparatus of claim 13, further comprising:
a chamber shield including a bottom and one or more side walls extending from the bottom,
wherein the semiconductor processing chamber includes one or more chamber walls and a chamber bottom, and
wherein the chamber shield is positioned in the semiconductor processing chamber such that:
the bottom of the chamber shield is adjacent to and offset from the chamber bottom by a first offset distance;
the chamber shield is supported by one or more supports that span between the chamber shield bottom and the chamber bottom;
the one or more side walls of the chamber shield are adjacent to and offset from the one or more chamber walls by a second offset distance; and
the pedestal base, the thermal shield, and the thermal shield collar are positioned above the bottom of the chamber shield.

15. The apparatus of claim 14, wherein:
the first offset distance is between about 0.05 inches and about 2 inches; and
the second offset distance is between about 0.05 inches and about 2 inches.

16. The apparatus of claim 14, further comprising:
a showerhead positioned in the chamber,
wherein:
the showerhead has an outer surface that faces the substrate support; and
the one or more side walls of the chamber shield are vertically offset above the outer surface of the showerhead when viewed at an angle perpendicular to the center axis.

17. The apparatus of claim 13, wherein:
the collar body further comprises one or more constraint surfaces in the top region; and
when the one or more first mating surfaces are in contact with the one or more second mating surfaces, the one or more constraint surfaces prevent radial movement of the thermal shield with respect to the collar center axis.

18. The apparatus of claim 13, wherein:
the body of the thermal shield includes an annular region that extends around the center axis and that has:
an outer circumferential boundary;
an inner boundary;
a radial width spanning between the outer circumferential boundary and the inner boundary in a direction perpendicular to the center axis; and
a first thickness in a direction parallel to the center axis that decreases as the radial distance decreases as a function of proximity to the center axis; and
the first thickness is less than or equal to 0.5 inches.

19. The apparatus of claim 13, wherein the collar body of the thermal shield collar includes a first tubular region that:
extends around the collar center axis;
is at least partially defined by a first collar top circumferential boundary and a first collar bottom circumferential boundary offset from the first collar top circumferential boundary by a first height along the collar center axis of the collar body, the first collar top circumferential boundary being closer to the top region than the first collar bottom circumferential boundary; and
has a second thickness in a direction perpendicular to the collar center axis and along the collar center axis that decreases as the distance from the top region increases.

20. The apparatus of claim 13, wherein:
the thermal shield collar includes a plurality of feet in the bottom region and a bottom surface in the bottom region;
each foot includes one of the support surfaces;
each foot extends away from the bottom surface along the collar center axis by a second distance such that the corresponding support surface is offset from the bottom surface by the second distance;
the support surfaces are in contact with a collar support surface of the substrate support; and
the bottom surfaces are not in contact with the collar support surface.
